(19) United States
(12) Patent Application Publication
(10) Pub. No.: US 2023/0042681 A1
(43) Pub. Date: Feb. 9, 2023

(54) SPAD PIXEL FOR A BACKSIDE ILLUMINATED IMAGE SENSOR

(71) Applicant: DB HiTek Co., Ltd., Bucheon-si (KR)

(72) Inventor: Man Lyun HA, Mungyeong-si (KR)

(21) Appl. No.: 17/812,365

(22) Filed: Jul. 13, 2022

(30) Foreign Application Priority Data
Aug. 5, 2021 (KR) 10-2021-0103009

(51) Int. Cl. H01L 27/146

(52) U.S. Cl. CPC H01L 27/1461; H01L 27/14649; H01L 27/14627; H01L 27/1463; H01L 27/1464

(57) ABSTRACT

Disclosed is a SPAD pixel for a backside illuminated image sensor. More particularly, the SPAD pixel may improve sensitivity to long wavelengths by maximizing the depth of a PN junction in an epitaxial layer in the SPAD substrate.

### CROSS REFERENCE TO RELATED APPLICATION

The present application claims priority to Korean Patent Application No. 10-2021-0103009, filed Aug. 5, 2021, the entire contents of which are incorporated herein for all purposes by this reference.

### BACKGROUND OF THE INVENTION

### Field of the Invention

The present disclosure relates to a SPAD pixel structure for a backside illuminated image sensor. More particularly, the present disclosure relates to a SPAD pixel structure for improving sensitivity to long wavelengths by maximizing the thickness of an epitaxial layer in a substrate.

### Description of the Related Art

In general, single-photon avalanche diodes, which are referred to as SPADs, are used as photoelectric conversion devices in pixels of an imaging device. The SPADs have PN junctions to detect incident radiation, and may operate in Geiger mode, that is, a mode operating with a voltage much higher than a breakdown voltage, which is also referred to as an avalanche voltage, of a single-photon avalanche diode. Since a voltage exceeding the breakdown voltage is applied to a SPAD, an electron avalanche occurs due to carriers generated by photoelectric conversion, and the SPAD enters a breakdown state. As a result, carrier amplification caused by photoelectric conversion occurs, and the sensitivity in the imaging device may be improved.

FIG. 1 is a cross-sectional view showing a unit pixel in a general double (two)-ended SPAD structure.

Hereinafter, a general SPAD structure will be described with reference to FIG. 1.

General SPAD structures may be classified into a single-ended SPAD type and a double-ended SPAD type. In a double-ended SPAD structure 9, an individual unit pixel area P1 in a pixel area P containing a plurality of the unit pixel areas P1 will be described with reference to FIG. 1 for illustrative purposes. In a substrate 901 having a first conductivity type, an impurity region 910 having a second conductivity type is formed, and in the impurity region 910, an impurity region 920 having the first conductivity type is formed at the surface of the substrate 901. Therefore, an avalanche amplification region is formed at the PN junction of the interface between the impurity region 910 having the second conductivity type and the impurity region 920 having the first conductivity type.

In addition, the impurity region 920 having the first conductivity type is electrically connected to an anode 930, and the impurity region 910 having the second conductivity type is electrically connected to a cathode 940. As a voltage higher than a breakdown voltage is applied between the anode 930 and the to cathode 940, the light absorbed into one side of the substrate 901 generates electrons through photoelectric conversion. The generated electrons move to the avalanche amplification region, thus causing avalanche amplification.

FIG. 2 is a graph showing absorption coefficients of silicon over a wavelength range.

Referring to FIG. 2, in general, a time-of-flight (ToF) sensor mainly uses a near-infrared (NIR) region with a wavelength of 900 nm. The light in the NIR region has a low absorption coefficient in the substrate 901, and may reach the depths of the substrate 901 without being absorbed. Herein, in the double-ended SPAD structure 9, the PN junction is formed such that the region does not expand vertically (e.g., in the upward-downward direction), inevitably degrading sensitivity in the junction. Therefore, in order to improve sensitivity of the device 9 to NIR wavelengths, a deep PN junction may be formed by high energy implantation, but this entails an inconvenient process.

The foregoing is intended merely to aid in the understanding of the background of the present disclosure, and is not intended to mean that the present disclosure falls within the purview of the related art that is already known to those skilled in the art.

### DOCUMENT OF RELATED ART

Korean Patent Application Publication No. 10-2019-0049598, “SPAD IMAGE SENSOR AND ASSOCIATED FABRICATING METHOD.”

### SUMMARY OF THE INVENTION

To solve the problem(s) in the related art, the present inventor conceived a new SPAD pixel structure that does not require a high energy implantation process during manufacturing and that may have an improved sensitivity to long wavelengths of light (e.g., NIR light).

The present disclosure is directed to a SPAD pixel for a backside illuminated image sensor, wherein first and second impurity doped regions having different conductivity types are not in contact with each other, but are at a front surface and a rear surface of a substrate, respectively, to maximize the depth of a PN junction in an epitaxial layer in the substrate, preserve the functionality of the SPAD pixel, and improve sensitivity of the SPAD pixel to long wavelengths of light.

In addition, the present disclosure is directed to a SPAD pixel for a backside illuminated image sensor, where the first impurity doped region and the second impurity doped region are at the front surface and the rear surface of the substrate, respectively, as described above, and the manufacturing process thereof does not require a high energy implantation process.

In addition, the present disclosure is directed to a SPAD pixel for a backside illuminated image sensor having a first metal wire above or below a front surface of a substrate and a second metal wire is at or above a rear surface of the substrate so as to prevent a decrease in efficiency and/or distortion of light incident to a microlens.

In addition, the present disclosure is directed to a SPAD pixel for a backside illuminated image sensor comprising a deep trench isolation (DTI) structure at a boundary of a unit pixel, thereby achieving electrical/physical isolation between adjacent unit pixels.

In addition, the present disclosure is directed to a SPAD pixel for a backside illuminated image sensor, wherein a metal contact is at an interface with a front surface of a substrate and a second metal wire is in a second substrate, so that a photodetector output circuit and a Vop may be realized on the same chip.

An embodiment of the present disclosure related to a SPAD pixel structure for a backside illuminated image sensor, the structure including a substrate having a front surface and a rear surface; a microlens above the rear surface of the substrate; a first impurity doped region having a first conductivity type or a second conductivity type at the front surface of the substrate; a heavily doped first contact region in the first impurity doped region and at the front surface of the substrate, having the same conductivity type as the first impurity doped region; a second impurity doped region at or near the rear surface of the substrate, having a different conductivity type from the first impurity doped region; and a heavily doped second contact region at the rear surface of the substrate and on the second impurity doped region, having the same conductivity type as the first impurity doped region.

According to another embodiment of the present disclosure, the SPAD pixel for the backside illuminated image sensor may further include an isolation film at a boundary between adjacent unit pixels, wherein the isolation film may extend from the rear surface to the front surface of the substrate, and may include a protective film at a lateral part or along a sidewall of the isolation film.

According to still another embodiment of the present disclosure, in the SPAD pixel for the backside illuminated image sensor, the protective film may comprise a heavily doped impurity region of the same conductivity type as the first contact region.

According to still another embodiment of the present disclosure, the SPAD pixel for the backside illuminated image sensor may further include a first metal contact at an interface with the front surface of the substrate; a first metal wire electrically connected to the metal contact (and optionally with a photodetector output circuit); and a second metal contact at or above the rear surface of the substrate.

According to still another embodiment of the present disclosure, in the SPAD pixel for the backside illuminated image sensor, the second metal contact may have a shape of a grid.

According to still another embodiment of the present disclosure, in the SPAD pixel for the backside illuminated image sensor, the second metal contact may be in ohmic contact with the second contact region.

According to still another embodiment of the present disclosure, in the SPAD pixel for the backside illuminated image sensor, the metal wire may function as an anode, and the second metal contact may function as a cathode.

According to still another embodiment of the present disclosure, there is provided a SPAD pixel for a backside illuminated image sensor, including a substrate having a front surface and a rear surface; a first impurity doped region having a first conductivity type or a second conductivity type at the front surface of the substrate; a first contact region in the first impurity doped region and at the front surface of the substrate; a second impurity doped region at or near the rear surface of the substrate, having a different conductivity type from the first impurity doped region; a second contact region at the rear surface of the substrate and on the second impurity doped region; an anode at or above the rear surface of the substrate, and a cathode above, below or near the front surface of the substrate, wherein the first impurity doped region and the second impurity doped region do not form a PN junction during operation of the SPAD pixel.

According to still another embodiment of the present disclosure, the SPAD pixel for the backside illuminated image sensor may further include an isolation film at a boundary between adjacent unit pixels, wherein the cathode may have a shape of a grid, is above the rear surface of the substrate and/or on the isolation film, and may have a surface in contact with the second contact region.

According to still another embodiment of the present disclosure, in the SPAD pixel for the backside illuminated image sensor, the isolation film may comprise a deep trench isolation (DTI) structure.

According to still another embodiment of the present disclosure, in the SPAD pixel for the backside illuminated image sensor, the cathode may be in ohmic contact with the second contact region.

According to still another embodiment of the present disclosure, there is provided a SPAD pixel for a backside illuminated image sensor, including a substrate having a front surface and a rear surface; a first impurity doped region having a first conductivity type or a second conductivity type at the front surface of the substrate; a first contact region in the first impurity doped region and at the front surface of the substrate; a second impurity doped region at or near the rear surface of the substrate, having a different conductivity type from the first impurity doped region; a second contact region at the rear surface of the substrate and on the second impurity doped region; a first metal contact at an interface with the front surface of the substrate; a first metal wire electrically connected to the first metal contact (and optionally with a photodetector output circuit); a second metal contact at the interface with the front surface of the substrate; and a second metal wire electrically connected to the second metal contact.

According to still another embodiment of the present disclosure, in the SPAD pixel for the backside illuminated image sensor, the first metal wire and the second metal wire may be in a second substrate.

According to still another embodiment of the present disclosure, the SPAD pixel for the backside illuminated image sensor may further include, at a boundary between adjacent unit pixel areas, an isolation film extending from the front surface to the rear surface of the substrate, wherein the isolation film may comprise an insulator surrounding a conductive plug.

According to still another embodiment of the present disclosure, in the SPAD pixel for the backside illuminated image sensor, the second metal wire may be electrically connected to the isolation film.

According to still another embodiment of the present disclosure, the SPAD pixel for the backside illuminated image sensor may further include a third metal contact at or above the rear surface of the substrate.

According to still another embodiment of the present disclosure, in the SPAD pixel for the backside illuminated image sensor, the third metal contact may have a shape of a grid, and may be electrically connected to the isolation film.

According to still another embodiment of the present disclosure, in the SPAD pixel for the backside illuminated image sensor, the third metal contact may be in ohmic contact with the second contact region.

According to still another embodiment of the present disclosure, in the SPAD pixel for the backside illuminated image sensor, the isolation film may include a heavily doped protective film having the same conductivity type as the first contact region.

According to the present disclosure, neither the first impurity doped region nor the second impurity doped region surrounds the other, but are at the front surface and the rear surface of the substrate, respectively, so that the depth of the PN junction in the epitaxial layer in the SPAD pixel substrate can be maximized to improve sensitivity to long wavelengths of light.

In addition, according to the present disclosure, the first impurity doped region and the second impurity doped region are at the front surface and the rear surface of the substrate, respectively, as described above, and the manufacturing process thereof does not require a high energy implantation process.

In addition, according to the present disclosure, a first metal wire is above, below or near the front surface of the substrate and a second metal wire may be at or above the rear surface of the substrate, so that a decrease in efficiency and distortion of light incident to the microlens can be prevented.

In addition, according to the present disclosure, an isolation film comprising a DTI structure may be at a boundary of the unit pixels, thereby achieving electrical/physical isolation between adjacent unit pixels.

In addition, according to the present disclosure, a metal contact a plurality of metal wires are in a second substrate, bonded to the front surface of the substrate, so that a photodetector output circuit and an amplifier circuit (Vop) can be on the same chip.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view showing a unit pixel in a general double (two)-ended SPAD structure;

FIG. 2 is a graph showing absorption coefficients of silicon over a wavelength range;

FIG. 3 is a plan view showing a single-photon avalanche diode (SPAD) pixel array in a backside illuminated image sensor according to a first exemplary embodiment of the present disclosure;

FIG. 4 is a cross-sectional view showing unit pixels in the SPAD pixel array of FIG. 3;

FIG. 5 is a cross-sectional view showing SPAD pixels in a backside illuminated image sensor according to a second exemplary embodiment of the present disclosure;

FIG. 6 is a cross-sectional view showing SPAD pixels in a backside illuminated image sensor according to a third exemplary embodiment of the present disclosure; and

FIG. 7 is a cross-sectional view showing SPAD pixels in a backside illuminated image sensor according to a fourth exemplary embodiment of the present disclosure.

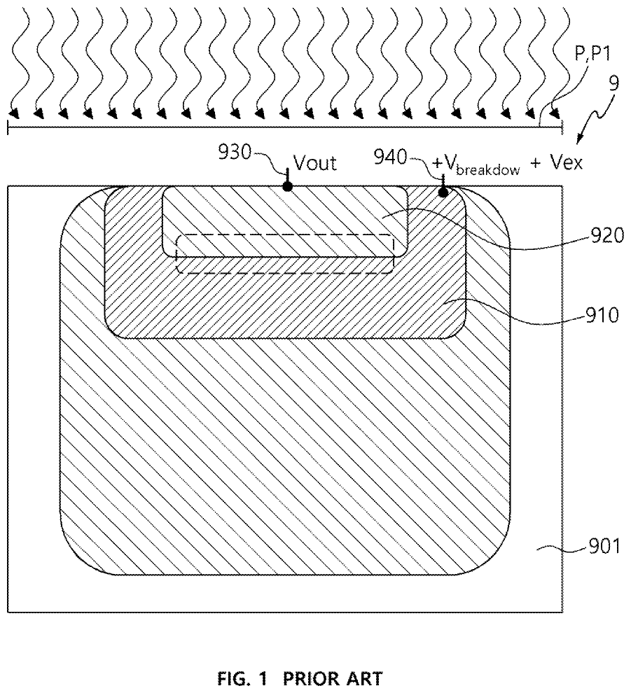

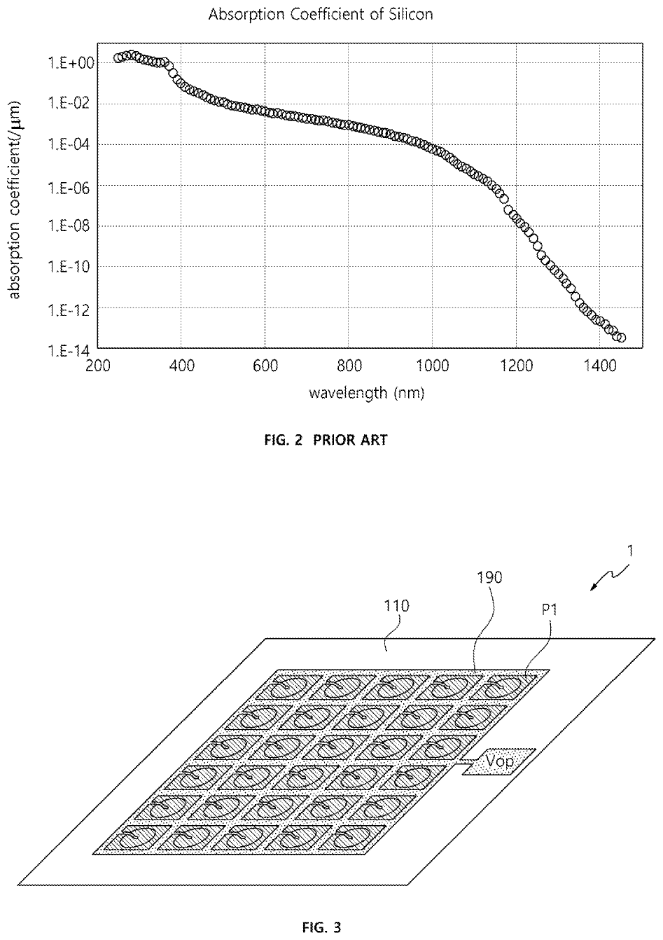

### DETAILED DESCRIPTION OF THE INVENTION

Hereinafter, embodiments of the present disclosure will be described in detail with reference to the accompanying drawings. It is noted that embodiments of the present disclosure may be changed to a variety of embodiments. The scope of the present disclosure should not be interpreted as being limited to the embodiments described hereinbelow, but should be interpreted on the basis of the descriptions in the appended claims. In addition, the embodiments of the present disclosure are provided for reference in order to fully describe the disclosure for those skilled in the art.

Unless otherwise mentioned in context, a singular noun or a singular noun phrase may have a plural meaning through the present specification. The terms “comprise” and/or “comprising” that are used in the present specification are intended to indicate that a shape, a number, a step, an operation, a member, an element, a group thereof, etc., are present, and do not preclude the presence or addition of one or more other shapes, numbers, steps, operations, members, elements, groups thereof, etc.

It should be noted that, in a case where one element (or layer) is described as being on another element (or layer), this means that the one element may be directly on the other element, or one or more third elements or layers may be therebetween. In addition, in the case where one element is described as being directly on another element, no third element is therebetween. In addition, one element being on a “top,” “upper portion,” “lower portion,” “above,” “below,” or on “one lateral side” or “lateral surface” of another element means a relative positional relationship between the two elements.

In addition, the terms first, second, etc. may be used in order to describe various and/or multiple items, such as elements, regions, and/or portions, but the existence of a second element does not presuppose the existence of a first element.

In addition, conductivity types or doped areas may be defined as “p-type” or “n-type” according to main carrier characteristics, but this is only for convenience of description, and the technical idea of the present disclosure is not limited thereto. For example, hereinafter, “p-type” and “n-type” may be referred to using the more general terms “first conductivity type” and “second conductivity type.” Herein, “first conductivity type” may refer to p-type, and “second conductivity type” may refer to n-type.

In addition, it is to be understood that the terms “heavily” and “lightly,” referring to a doping concentration in an impurity region, refer to a relative doping concentration of one element or region relative to another element or region.

In the present specification, according to need, individual elements may be integral with each other or independent of each other. It should be noted that no specific limitation to these formations is imposed.

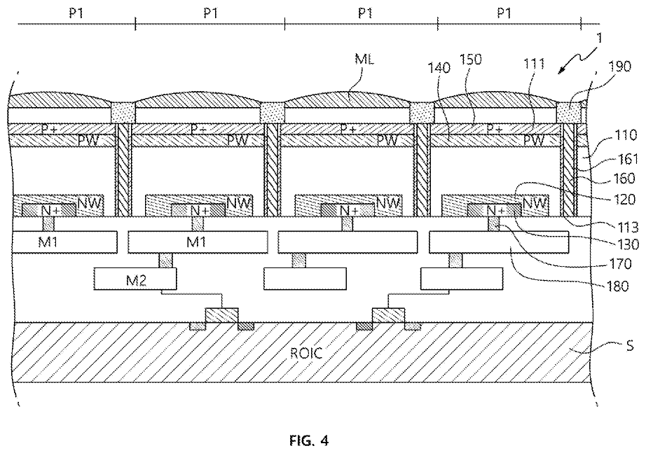

FIG. 3 is a plan view showing a single-photon avalanche diode (SPAD) pixel array in a backside illuminated image sensor according to a first exemplary embodiment of the present disclosure. FIG. 4 is a cross-sectional view showing unit pixels in the SPAD pixel structure of FIG. 3.

Hereinafter, a single-photon avalanche diode (SPAD) pixel array 1 in a backside illuminated image sensor according to the first exemplary embodiment of the present disclosure will be described in detail with reference to the accompanying drawings.

Referring to FIGS. 3 and 4, the present disclosure relates to a SPAD pixel array 1 in a backside illuminated image sensor. More particularly, the present disclosure relates to a SPAD pixel that improves sensitivity to long wavelengths by maximizing the depth of a PN junction in an epitaxial layer in the SPAD pixel substrate. Details will be described. It should be noted that the present disclosure is applicable to either a single-ended SPAD pixel or a double (two)-ended SPAD pixel, and limitation thereto is not imposed. In addition, it is understood that the array 1 according to the first exemplary embodiment described below is applied to a single-ended SPAD pixel.

First, the array 1 according to the first exemplary embodiment of the present disclosure includes a substrate 110 having a front surface 113 and a rear surface 111. The substrate 110 comprises a lightly doped impurity region having a first conductivity type or a second conductivity type, and may be formed by epitaxial growth (e.g., on a single-crystal silicon wafer, which may be sacrificial). When the substrate 110 is doped with impurities having the first conductivity type, an avalanche amplification region is at a PN junction with a first impurity doped region 120, which will be described later, having the second conductivity type. Conversely, in the case in which the substrate is doped with impurities having the second conductivity type, an avalanche amplification region is at a PN junction with a second impurity doped region 140, which will be described later.

The first impurity doped region 120 is at the front surface 113 of the substrate 110, and may be under the front surface 113 of the substrate 110 and/or in the substrate 110. The first impurity doped region 120 may be an impurity doped region having the second conductivity type. In addition, a first contact region 130 may be in the first impurity doped region 120. The first contact region 130 may be covered or surrounded on all but one side by the first impurity doped region 120, but is not limited thereto. The first contact region 130 is an impurity doped region having the second conductivity type, and is more heavily doped than the impurity doped region 120 having the second conductivity type, preferably. In addition, the first contact region 130 is electrically connected to a first metal contact 170 below the first contact region 130 and may function as an anode.

The first impurity doped region 120 may be formed, for example, by ion implantation into the front surface 113 of the substrate 110 using a first mask with openings corresponding to the dimensions of the first impurity doped region 120. At the time of this ion implantation, the substrate S is not yet connected to the front surface 113 of the substrate 110. The first contact region 130 may also be formed, for example, by ion implantation into the front surface 113 of the substrate 110 using a second mask with openings corresponding to the dimensions of the first contact region 130, but typically at a higher dose and a lower implantation energy than the first impurity doped region 120.

The second impurity doped region 140 is at the rear surface 111 of the substrate 110, and the region 140 may be an impurity doped region having the first conductivity type. In addition, a second contact region 150 is on the second impurity doped region 140, and the second contact region 150 may be an impurity region having the first conductivity type that is more heavily doped than the second impurity doped region 140. In addition, the second contact region 150 may have an interface with the second impurity doped region 140 that is substantially parallel with the rear surface 111 of the substrate 110. That is, the second impurity doped region 140 and the second contact region 150 may be stacked when viewed in a cross section. Therefore, the entire surface of the second contact region 150 away from the second impurity doped region 140 may be at the rear surface 111 of the substrate 110. The second contact region 150 may be in contact with a second metal contact 190, which will be described later, and may have the shape of a grid, in the unit pixel areas P1.

The second impurity doped region 140 may be formed, for example, by ion implantation into the rear surface 111 of the substrate 110. Typically, this ion implantation is conducted after the substrate 110 is bonded to the substrate S at the front surface 113, then the substrate 110 is cleaved to remove a sacrificial portion of the substrate (e.g., a single-crystal silicon wafer, on which the epitaxial layer 110 is deposited before formation of the first impurity doped region 120 and the first contact region 130). The second contact region 150 may also be formed by ion implantation into the rear surface 111 of the substrate 110, but typically at a higher dose and a lower implantation energy than the second impurity doped region 140. In this case, there is no need for ion implantation through a mask during formation of either the second impurity doped region 140 or the second contact region 150, but in some embodiments, a mask blocking implantation into peripheral regions of the substrate 110 (not shown) may be used in the ion implantations to form the second impurity doped region 140 and the second contact region 150. Alternatively, the second impurity doped region 140 and the second contact region 150 may be formed by blanket deposition (e.g., of silicon from silane gas and the first conductivity type dopant from a gas-phase source thereof).

As described above, the first impurity doped region 120 having the second conductivity type is at the front surface 113 of the substrate 110, and the second impurity doped region 140 having the first conductivity type is at the rear surface 111 of the substrate 110. That is, since the first impurity doped region 120 and the second impurity doped region 140 are not in contact with each other, the depth of the PN junction in the epitaxial layer 110 in the substrate 110 is prevented from being reduced, thus achieving excellent photon detection probability (PDP) for light in the NIR region, such as light having a wavelength of 900 nm. In addition, a high energy implantation process is not required to form the avalanche amplification region (e.g., a PN junction) at the depths in the substrate 110, particularly as in a double-ended SPAD pixel. This will be described in a second exemplary embodiment.

In addition, an isolation film 160 may be at the boundary of each unit pixel area P1. The isolation film 160 may extend from the front surface 113 to the rear surface 111 in each unit pixel area P1, or may extend by a length less than that between the rear surface 111 and the front surface 113. The isolation film 160 may comprise a deep trench isolation (DTI) structure. For example, after a deep trench is formed in the substrate 110 by deep reactive ion etching (DRIE), an oxide liner (not numbered) is formed on lateral surfaces of the trench, and the space inside the oxide liner is filled with undoped polysilicon, thereby forming the isolation film 160. However, no limitation thereto is imposed.

In addition, a protective film 161 may be on a lateral or vertical surface of the isolation film 160. The protective film 161 is formed by injecting impurities into the substrate 110 after the trench for the isolation film 160 is formed, and the impurities may have the second conductivity type, for example. In addition, the impurity injection may be performed using plasma-assisted doping (PLAD). The protective film 161 may be more heavily doped than the first impurity doped region 120, for example. Accordingly, the impurities in the first impurity doped region 120 do not diffuse into the isolation film 160.

In addition, the first metal contact 170 and a metal wire 180 may be at an opposite side of the front surface 113 of the substrate 110 from the first impurity doped region 120 and the first contact region 130. Both the first metal contact 170 and the metal wire 180 may be in an insulation layer, and a plurality of the first metal contacts 170 and the metal wires 180 may be repeatedly stacked in the upward-downward direction (as shown in FIG. 4). The first metal contact 170 is electrically connected to the first contact region 130 and may function as an anode. In addition, the metal wire 180 may be coupled to a photodetector output circuit (e.g., a readout integrated circuit, or ROIC) on the substrate S connected to the front surface 113 of the substrate 110.

Continuing the description, the second metal contact 190 is on or above the rear surface 111 of the substrate 110, and the second metal contact 190 may have the shape of a grid. That is, the second metal contact 190 may be at least partially on the isolation film 160. In addition, the second metal contact 190 may be in ohmic contact with the second contact region 150. The second metal contact 190 may serve as a cathode. Accordingly, the second metal contact 190 may be used as a Vop port. The second metal contact 190 may be formed by depositing a titanium (Ti) and/or titanium nitride (TiN) film, depositing a tungsten (W) film, and then etching the tungsten and titanium and/or titanium nitride films using a mask having one or more openings in the grid shape, for example. As described above, since the second metal contact 190 may be used as the Vop port, it is possible to prevent a decrease in efficiency and the occurrence of distortion of light incident on the microlens (ML) due to a separate metal wire or line to the anode or cathode.

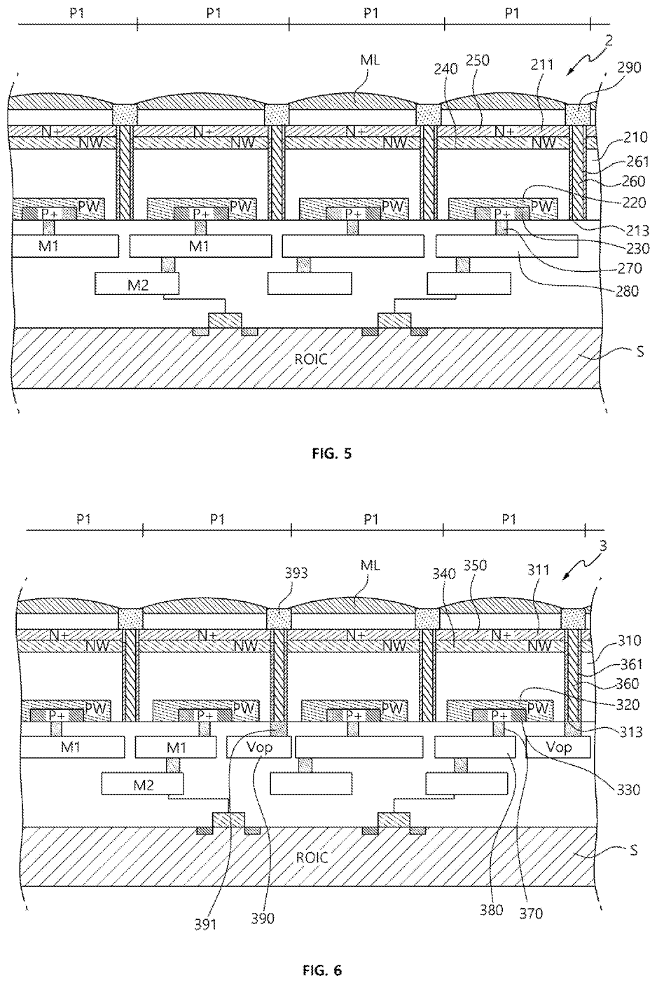

FIG. 5 is a cross-sectional view showing SPAD pixels for a backside illuminated image sensor according to a second exemplary embodiment of the present disclosure.

Hereinafter, a partial SPAD pixel array 2 in a backside illuminated image sensor according to the second exemplary embodiment of the present disclosure will be described in detail with reference to the accompanying drawings. It is understood the array 2 according to the second exemplary embodiment is applied to double-ended SPAD pixels. The elements and/or structures in the partial array 2 according to the second exemplary embodiment that are the same as those of the array 1 according to the first exemplary embodiment will not be described in detail.

FIG. 5 shows a substrate 210 having a front surface 213 and a rear surface 211. The substrate 210 comprises a lightly doped impurity region having a first conductivity type or a second conductivity type, which may be formed by epitaxial growth (e.g., on a sacrificial single-crystal silicon wafer, not shown). It is noted that the locations of PN junctions may vary according to the doping of impurities in the substrate 210.

In the array 2 according to the second exemplary embodiment, as in the first exemplary embodiment, a first impurity doped region 220 may be at the front surface 213 of the substrate 210, and a first contact region 230 may be in the first impurity doped region 220. The first impurity doped region 220 is an impurity doped region having the first conductivity type, and the first contact region 230 may be an impurity region having the first conductivity type that is more heavily doped than the first impurity doped region 220. The first impurity doped region 220 and the first contact region 230 may be formed in the same manner as the first impurity doped region 120 and the first contact region 130 in FIG. 4, except that the conductivity type of the first impurity doped region 220 and the first contact region 230 is different from that of the first impurity doped region 120 and the first contact region 130.

In addition, a second impurity doped region 240 is at the rear surface 211 of the substrate 210. A second contact region 250 is on the second impurity doped region 240, and is at the rear surface 213. Both the second impurity doped region 240 and the second contact region 250 are impurity doped regions having the second conductivity type. The second contact region 250 may be a more heavily doped region. The second impurity doped region 240 and the second contact region 250 may be formed in the same manner as the second impurity doped region 140 and the second contact region 150 in FIG. 4, except that the conductivity type of the second impurity doped region 240 and the second contact region 250 is different from that of the second impurity doped region 140 and the second contact region 150.

In addition, an isolation film 260 is at the boundary of each unit pixel area P1. A protective film 261 that is an impurity injection region having the first conductivity type may be at a lateral part of the isolation film 260. The protective film 261 may be a region into which impurities are injected using plasma-assisted doping, and may formed by injecting impurities having the first conductivity type, such as boron (B), for example. In addition, preferably, the protective film 261 is a region that is more heavily doped than the first impurity doped region 220.

Continuing the description, in the array 2 according to the second exemplary embodiment, a first metal contact 270, a metal wire 280, and a second metal contact 290 may be similar to the corresponding configuration of the first exemplary embodiment. The second metal contact 290 may be in the shape of a grid above the rear surface 211 and may be in ohmic contact with the second contact region 250.

As described above, in general, a time-of-flight (ToF) sensor mainly uses near-infrared (NIR) light (e.g., having a wavelength of 900 nm). The light in the NIR region has a low absorption coefficient in the substrate 210, and may reach the depths of the substrate 210 without being absorbed. Accordingly, as described above, in a conventional double-ended SPAD structure, a high energy implantation process may be performed to form a PN junction that may expand to the depths of the substrate 210. However, in the array 2 according to the second exemplary embodiment of the present disclosure, the first impurity doped region 220 is at the rear surface 213 of the substrate 210, and the second impurity doped region 240 is at the front surface 213, so that a PN junction is formed relatively deep in the epitaxial layer 210 having a relatively large effective thickness, and the sensitivity to long wavelengths of light (e.g., in the NIR range) is improved without a high energy implantation process.

FIG. 6 is a cross-sectional view showing a SPAD pixel for a backside illuminated image sensor according to a third exemplary embodiment of the present disclosure.

Hereinafter, a SPAD pixel array 3 for a backside illuminated image sensor according to the third exemplary embodiment of the present disclosure will be described in detail with reference to the accompanying drawings. The array 3 according to the third exemplary embodiment is applied to a double-ended SPAD pixel structure, and only the elements different from those of the array 2 according to the second exemplary embodiment will be described in detail.

Referring to FIG. 6, in the array 3 according to the third exemplary embodiment, a second metal wire 390 may be in the substrate S near the front surface 313 of the substrate 310. The second metal wire 390 may be electrically connected to the isolation film 360 via a metal contact 391 at the interface with the substrate 310. Herein, the metal wire 380 is referred to as a first metal wire 380. In addition, a protective film 361 is at the outermost lateral part of the isolation film 360, along the sidewall(s) of the trench or via in which the isolation film 360 is deposited. one or more insulating liner layers may be in the isolation film 360 and may surround a conductive plug therein. The conductive plug may be electrically connected to the second metal wire 390 through the second metal contact 391. The conductive plug may comprise, for example, tungsten, but is not limited thereto. The conductive plug may comprise any metal, metal alloy or metal compound having sufficient electrical conductivity to electrically connect the cathode metal contact 393 to the second metal wire 390. In addition, the metal contact 393 has the same structure as the second metal contact 190 of the first exemplary embodiment. The metal contact 393 is also electrically connected to a second contact region 330.

Accordingly, the array 3 according to the third exemplary embodiment may further include a photodetector output circuit (e.g., a readout integrated circuit, or ROIC) and a Vop on the same chip (e.g., the substrate S).

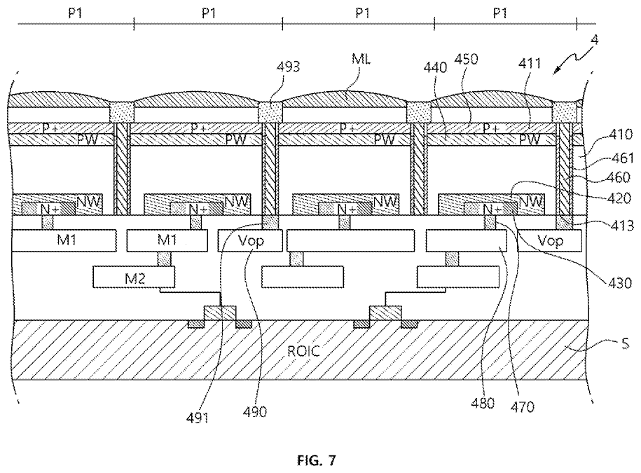

FIG. 7 is a cross-sectional view showing a SPAD pixel for a backside illuminated image sensor according to a fourth exemplary embodiment of the present disclosure.

Hereinafter, a SPAD pixel array 4 for a backside illuminated image sensor according to the fourth exemplary embodiment of the present disclosure will be described in detail with reference to the accompanying drawings. The array 4 according to the fourth exemplary embodiment is applied to a single-ended SPAD pixel, and is a combination of the array 1 according to the first exemplary embodiment and the structure 3 according to the third exemplary embodiment.

That is, referring to FIG. 7, a protective film 461 is at a lateral part (e.g., along sidewalls) of an isolation film 460. The isolation film 460 may comprise an insulator liner and a conductive plug therein, similar to the array 3 in FIG. 6. A second metal wire 490 may be in or above the substrate S, and a second metal contact 491 may be at an interface with the front surface 413 of the substrate 410. The other elements have the same structure and function as those of the array 1 according to the first exemplary embodiment.

The foregoing detailed description illustrates the present disclosure. In addition, the foregoing illustrates and describes the preferred embodiments of the present disclosure and the present disclosure may be utilized in various other combinations, modifications and environments. That is, it is possible to make changes or modifications within the scope of the concept of the disclosure disclosed herein, within the scope of equivalents to the above described disclosure, and/or within the scope of the skill or knowledge of the art. The above-described embodiments are intended to describe the best mode for carrying out the technical spirit of the present disclosure, and various modifications required in the specific applications and uses of the present disclosure are possible. Accordingly, the foregoing detailed description is not intended to limit the present disclosure to the embodiments disclosed.

What is claimed is:

1. A SPAD pixel structure, comprising:
a substrate having a front surface and a rear surface;
a microlens above the rear surface of the substrate;
a first impurity doped region having a first conductivity type or a second conductivity type at the front surface of the substrate;
a heavily doped first contact region in the first impurity doped region and at the front surface of the substrate, having a same conductivity type as the first impurity doped region;
a second impurity doped region at or near the rear surface of the substrate, having a different conductivity type from the first impurity doped region; and
a heavily doped second contact region at the rear surface of the substrate and on the second impurity doped region, having a same conductivity type as the second impurity doped region.

2. The structure of claim 1, further comprising:
an isolation film at a boundary between adjacent unit pixels,
wherein the isolation film extends from the rear surface of the substrate to the front surface thereof, and comprises a protective film at a lateral part or along a sidewall of the isolation film.

3. The structure of claim 2, wherein the protective film is a heavily doped impurity region of the same conductivity type as the first contact region.

4. The structure of claim 2, further comprising:
a first metal contact at an interface with the front surface of the substrate;
a metal wire electrically connected to the first metal contact; and
a second metal contact above the rear surface of the substrate.

5. The structure of claim 4, wherein the second metal contact has a shape of a grid.

6. The structure of claim 4, wherein the second metal contact is in ohmic contact with the second contact region.

7. The structure of claim 6, wherein the metal wire functions as an anode, and
the second metal contact functions as a cathode.

8. A SPAD pixel for a backside illuminated image sensor, comprising:
a substrate having a front surface and a rear surface;
a first impurity doped region having a first conductivity type or a second conductivity type at the front surface of the substrate;
a first contact region in the first impurity doped region and at the front surface of the substrate;
a second impurity doped region at or near the rear surface of the substrate, having a different conductivity type from the first impurity doped region;
a second contact region at the rear surface of the substrate and on the second impurity doped region;
an anode at or above the rear surface of the substrate; and
a cathode above, below or near the front surface of the substrate,
wherein the first impurity doped region and the second impurity doped region do not form a PN junction during operation of the SPAD pixel.

9. The SPAD pixel of claim 8, further comprising:
an isolation film at a boundary between adjacent unit pixels,
wherein the cathode has a shape of a grid, is above the rear surface of the substrate and/or on the isolation film, and has a surface in contact with the second contact region.

10. The SPAD pixel of claim 8, wherein the isolation film comprises a deep trench isolation (DTI) structure.

11. The SPAD pixel of claim 10, wherein the cathode is in ohmic contact with the second contact region.

12. A SPAD pixel for a backside illuminated image sensor, comprising:
a substrate having a front surface and a rear surface;
a first impurity doped region having a first conductivity type or a second conductivity type at the front surface of the substrate;
a first contact region in the first impurity doped region and at the front surface of the substrate;
a second impurity doped region at or near the rear surface of the substrate, having a different conductivity type from the first impurity doped region;
a second contact region at the rear surface of the substrate and on the second impurity doped region;
a first metal contact at an interface with the front surface of the substrate;
a first metal wire electrically connected to the first metal contact;
a second metal contact at the interface with the front surface of the substrate; and
a second metal wire electrically connected to the second metal contact.

13. The SPAD pixel of claim 12, wherein the first metal wire and the second metal wire are in a second substrate.

14. The SPAD pixel of claim 13, further comprising:
an isolation film at a boundary between adjacent unit pixels, extending from the front surface to the rear surface of the substrate,
wherein the isolation film comprises an insulator surrounding a conductive plug.

15. The SPAD pixel of claim 14, wherein the second metal wire is electrically connected to the isolation film.

16. The SPAD pixel of claim 15, further comprising:
a third metal contact at or above the rear surface of the substrate.

17. The SPAD pixel of claim 16, wherein the third metal contact is electrically connected to the isolation film.

18. The SPAD pixel of claim 17, wherein the third metal contact is in ohmic contact with the second contact region.

19. The SPAD pixel of claim 14, wherein the isolation film comprises a heavily doped protective film having a same conductivity type as the first contact region.
